(19) United States
(12) Patent Application Publication
(10) Pub. No.: US 2024/0419953 A1
(43) Pub. Date: Dec. 19, 2024

(54) QUANTIZED MACHINE-LEARNING CONFIGURATION INFORMATION

(71) Applicant: Google LLC, Mountain View, CA (US)

(72) Inventors: Jibing Wang, San Jose, CA (US); Erik Stauffer, Mountain View, CA (US)

(21) Appl. No.: 18/701,168

(22) PCT Filed: Oct. 12, 2022
(86) PCT No.: PCT/US2022/046485

§ 371 Date: Apr. 12, 2024

Related U.S. Application Data
(60) Provisional application No. 63/255,376, filed on Oct. 13, 2021.

(51) Int. Cl. G06N 3/0495; H04W 72/04

(52) U.S. Cl. CPC G06N 3/0495; H04W 72/04

(57) ABSTRACT

Aspects describe communicating quantized machine-learning, ML, configuration information over a wireless network. A base station selects (605) a quantization configuration for quantizing ML configuration information for a deep neural network, DNN, where the quantization configuration indicates one or more quantization formats associated with quantizing the ML configuration information. The base station transmits (610) an indication of the quantization configuration to a user equipment, UE and transfers (615), over the wireless network and with the UE, quantized ML configuration information using the quantization configuration.

### CROSS-REFERENCE TO RELATED APPLICATIONS

This application claims the benefit of U.S. Provisional Patent Application No. 63/255,376, filed 13 Oct. 2021 the disclosure of which is incorporated herein by reference in its entirety.

### BACKGROUND

Machine-learning algorithms, such as deep neural networks (DNNs), provide solutions to complex processing. As an example, through training and feedback, a DNN dynamically modifies its behavior to predict and/or identify patterns in new (future) input data. This training and feedback not only teaches the DNN to perform the complex processing, but additionally provides flexibility to adapt the machine-learning algorithm based on changing input data. The complex processing, however, may result in machine-learning algorithms with complex architectures, such as a multi-layered DNN, where each layer of the DNN includes multiple nodes.

Generally, a machine-learning configuration specifies different machine-learning parameters (e.g., architecture types, node connections) that characterize a machine learning algorithm. To illustrate, a first device may communicate a machine-learning configuration to a second device, and the second device uses the machine-learning configuration to form the corresponding machine-learning algorithm (e.g., a DNN). Depending upon a complexity of the machine-learning algorithm, specifying a corresponding machine-learning configuration may entail large quantities of data. In various communication networks, such as wireless networks, communicating the machine-learning configuration from one device to a second device may consume large quantities of network resources. In a wireless network, the availability of these network resources (e.g., air interface resources) becomes strained as an increasing number of devices attempt to use the wireless network. Thus, to increase capacity and deliver reliable wireless connections, evolving communication systems look for new approaches to efficiently utilize the available resources and avoid waste.

### SUMMARY

This document describes techniques and apparatuses for wirelessly providing quantized machine-learning (ML) configurations that can be used to form and/or update a DNN implemented in a wireless communications processing chain, such as a wireless transmitter processing chain or a wireless receiver processing chain. A base station selects a quantization configuration for quantizing ML configuration information for a deep neural network (DNN), where the ML configuration information may include set-up information that forms the DNN and/or feedback information that specifies updates to the DNN. In aspects, the quantization configuration indicates one or more quantization formats associated with quantizing the ML configuration information. As one example, the base station transmits an indication of the quantization configuration to a user equipment (UE). The base station and the UE then transfer quantized ML configuration information to one another using the wireless network, where the transmitting device (e.g., either the base station or the UE) generates the quantized ML configuration information in accordance with the quantization configuration.

In some aspects, a UE receives, over a wireless network, a quantization configuration for quantizing the ML configuration information for a DNN, where the quantization configuration specifies one or more quantization formats associated with quantizing the ML configuration information. The UE communicates, over the wireless network and with a base station, quantized ML configuration information generated in accordance with the quantization configuration.

The details of one or more implementations of quantized ML configuration information are set forth in the accompanying drawings and the following description. Other features and advantages will be apparent from the description, drawings, and claims. This Summary is provided to introduce subject matter that is further described in the Detailed Description and Drawings. Accordingly, this Summary should not be considered to describe essential features nor used to limit the scope of the claimed subject matter.

### BRIEF DESCRIPTION OF THE DRAWINGS

The details of one or more aspects of quantized machine-learning (ML) configurations are described below. The use of the same reference numbers in different instances in the description and the figures indicate similar elements:

FIG. 1 illustrates an example environment in which various aspects of quantized ML configuration information can be implemented;

FIG. 2 illustrates an example device diagram of devices that can implement various aspects of quantized ML configuration information;

FIG. 3 illustrates an example operating environment in which multiple deep neural networks are utilized in a wireless communication system in accordance with various aspects of quantized ML configuration information;

FIG. 4 illustrates an example of generating ML configurations in accordance with aspects of quantized ML configuration information;

FIG. 5 illustrates an example transaction diagram between various devices in accordance with various aspects of quantized ML configuration information;

FIG. 6 illustrates an example method that can be used to perform various aspects of quantized ML configuration information; and

FIG. 7 illustrates an example method that can be used to perform various aspects of quantized ML configuration information.

### DETAILED DESCRIPTION

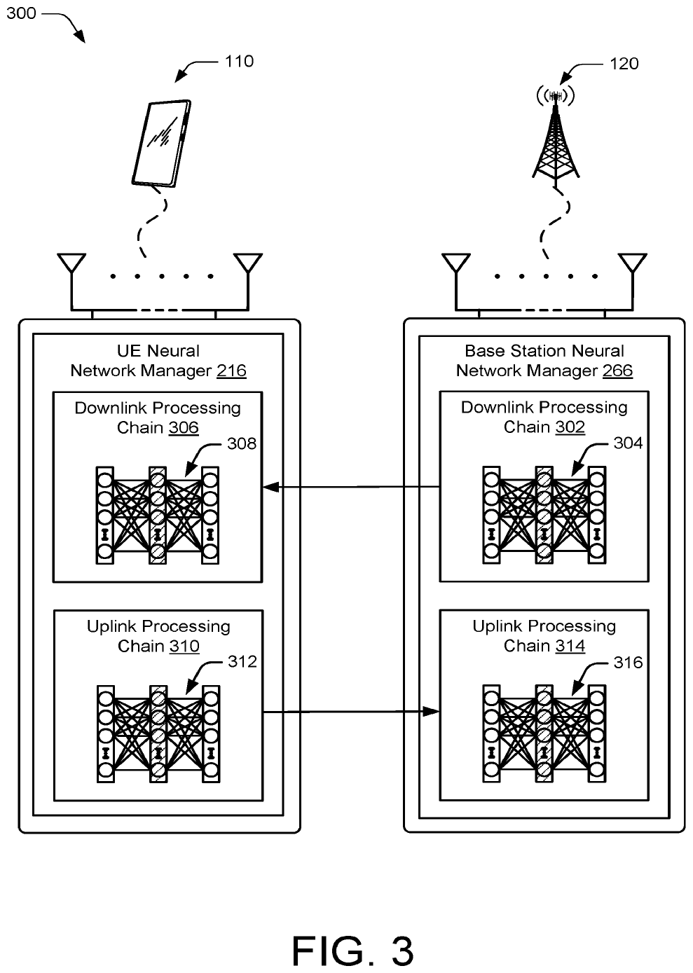

Deep neural networks (DNNs) provide solutions to complex processing, such as the complex processing performed by wireless communications transmitter and/or receiver processing chains. By training a DNN to perform transmitter and/or receiver processing chain operations, a device can replace conventional transmitter and/or receiver processing blocks (e.g., encoders, decoders, modulation processing blocks, demodulation processing blocks) with the DNN, which allows the device to dynamically adapt to changing operating conditions due to a variety of factors, such as user mobility, interference from neighboring cells, bursty traffic, and so forth. To illustrate, a base station selects an initial machine-learning (ML) configuration that forms a UE-side DNN for processing downlink communications as described with reference to FIG. 3, where the ML configuration specifies a combination of ML parameters that can be used to form a neural network (e.g., a DNN). The base station communicates the initial ML configuration over a wireless network to a UE and directs the UE(s) to form a UE-side DNN using the initial ML configuration. As operating conditions change, however, the UE may train the UE-side DNN to optimize processing for a current operating condition and communicate ML configuration updates to the base station using the wireless network.

As another example, the base station selects a common (initial) ML configuration for a group of UEs to use as a baseline for federated learning. Generally, federated learning corresponds to a distributed training mechanism for a machine-learning algorithm, where a managing device (e.g., the base station) communicates a baseline ML configuration (e.g., the common ML configuration) to a group of devices (e.g., the group of UEs). Each device generates training results, such as updates and/or changes to the common ML configuration, using local data, and communicates the training results to the managing device. The managing device then aggregates training results from the multiple devices to generate an updated ML configuration for the ML configuration.

Communicating ML configurations and/or ML configuration updates in a wireless network sometimes consumes large quantities of air interface resources, such as when the ML configuration pertains to a multi-layered DNN with multiple nodes and/or when the base station communicates with multiple UEs to determine ML configuration updates using federated learning. The availability of these air interface resources becomes strained as an increasing number of devices attempt to use the wireless network. To illustrate, assume a radio access network (RAN) allocates air interface resources to a first base station and a second base station, where each base station receives a finite allocation of air interface resources. The first base station serving a single user equipment (UE) may assign a majority of the respective air interface resources to the single UE, while a second base station serving multiple UEs divides the respective air interface resources amongst the multiple UEs. Because the allocated air interface resources have a finite size, a base station can only support a finite number of UEs at a given time. Thus, to increase capacity and deliver reliable wireless connections, it is desirable to increase the efficiency of how the corresponding resources of the wireless network are used and to reduce wasted resources. Communicating large quantities of information and/or data over a wireless network may also consume and drain power resources, such as a battery for a UE, because of the power used to transmit communications and/or receive and process the communications. Thus, it is also desirable to reduce power consumption and preserve a battery life.

In aspects, a base station selects a quantization configuration for quantizing ML configuration information. Generally, quantized ML configuration information corresponds to a quantized representation of ML configuration information (e.g., an ML configuration, an ML configuration update), where the quantized representation uses controlled, predetermined, and/or discrete values to indicate the ML configuration. To illustrate, assume that a UE determines to send, to the base station, an ML configuration update that includes 100 floating-point values, where each floating-point value corresponds to an ML parameter (e.g., weight value, bias value, gradient value) for a layer of a DNN. A quantized representation of the ML configuration update (e.g., a quantized ML configuration update) indicates the 100 floating-point values using the controlled, predetermined, and/or discrete representation, such as by indicating an index value that maps to an entry in a codebook that has the highest correlation to the 100 floating-point values and/or by communicating scalar values of a fixed size (e.g., 8-bit fixed size, 16-bit fixed size). Thus, a quantized representation reduces an amount of data and/or information transmitted in the wireless network, where the quantized representation may use different quantization formats. To illustrate, mapping the 100 floating-point values to an index value of a codebook corresponds to a first quantization format (e.g., a vector quantization format), and communicating scalar values of a fixed size corresponds to a second quantization format (e.g., a scalar quantization format).

A quantization configuration corresponds to a selection of one or more quantization formats. In selecting a quantization configuration, the base station selects one or more quantization formats for generating quantized representations of ML configuration information (e.g., an ML configuration, an ML configuration update) and communicates the quantization configuration to a UE. The base station and the UE use the quantization configuration to transfer quantized ML configuration information (e.g., a quantized ML configuration, a quantized ML configuration update) over the wireless network to one another. As one example, the base station generates quantized ML configuration information using the quantization configuration, transmits the quantized ML configuration to the UE using the wireless network, and the UE uses the quantization configuration to recover ML configuration information from the quantized ML configuration information. Alternatively or additionally, the UE uses the quantization configuration to generate and transmit quantized ML configuration information to the base station over the wireless network, and the base station uses the quantization configuration to recover the ML configuration information. In some aspects, the base station and/or UE apply the ML configuration information to a DNN using the quantization configuration (e.g., applying a scalar value to the quantized ML configuration information).

Communicating quantized ML configuration information reduces an amount of data and/or information used to communicate ML configurations and/or ML configuration updates. Accordingly, a transmitting device uses fewer air interface resources of the wireless network when transmitting the quantized ML configuration information relative to transmitting the ML configuration information and preserves the air interface resources of the wireless network for other tasks. To illustrate, the wireless network uses the preserved air interface resources for other devices and/or network operations, such as operations that increase or decrease data throughput, operations that reduce data-transfer latency, operations that improve signal quality, etc. This improves the wireless network's ability to meet changes in demand and/or address changing channel conditions, and subsequently improves the reliability of the services provided by the wireless network. This also reduces power consumption of a device by reducing transmissions processed by the device, whether transmitting or receiving the transmissions, thus preserving a corresponding battery life and/or power at the device.

### Example Environment

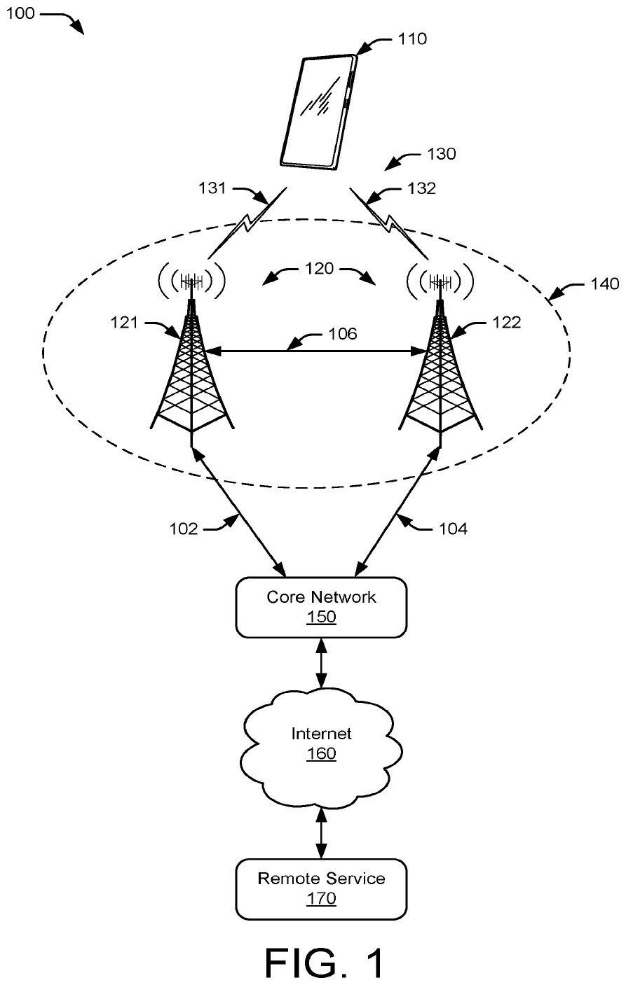

FIG. 1 illustrates an example environment 100, which includes a user equipment 110 (UE 110) that can communicate with base stations 120 (illustrated as base stations 121 and 122) through one or more wireless communication links 130 (wireless link 130), illustrated as wireless links 131 and 132. For simplicity, the UE 110 is implemented as a smartphone but may be implemented as any suitable computing or electronic device, such as a mobile communication device, modem, cellular phone, gaming device, navigation device, media device, laptop computer, desktop computer, tablet computer, smart appliance, vehicle-based communication system, or an Internet-of-Things (IoT) device such as a sensor or an actuator. The base stations 120 (e.g., an Evolved Universal Terrestrial Radio Access Network Node B, E-UTRAN Node B, evolved Node B, eNodeB, eNB, Next Generation Node B, gNode B, gNB, ng-eNB, or the like) may be implemented in a macrocell, microcell, small cell, picocell, distributed base station, and the like, or any combination or future evolution thereof.

The base stations 120 communicate with the user equipment 110 using the wireless links 131 and 132, which may be implemented as any suitable type of wireless link. The wireless links 131 and 132 include control and data communication, such as downlink of data and control information communicated from the base stations 120 to the user equipment 110, uplink of other data and control information communicated from the user equipment 110 to the base stations 120, or both. The wireless links 130 may include one or more wireless links (e.g., radio links) or bearers implemented using any suitable communication protocol or standard, or combination of communication protocols or standards, such as 3rd Generation Partnership Project Long-Term Evolution (3GPP LTE), Fifth Generation New Radio (5G NR), and future evolutions. In various aspects, the base stations 120 and UE 110 may be implemented for operation in sub-gigahertz bands, sub-6 GHz bands (e.g., Frequency Range 1), and/or above-6 GHz bands (e.g., Frequency Range 2, millimeter wave (mmWave) bands) that are defined by one or more of the 3GPP LTE, 5G NR, or 6G communication standards (e.g., 26 GHz, 28 GHz, 38 GHz, 39 GHz, 41 GHz, 57-64 GHz, 71 GHz, 81 GHz, 92 GHz bands, 100 GHz to 300 GHz, 130 GHz to 175 GHz, or 300 GHz to 3 THz bands). Multiple wireless links 130 may be aggregated in a carrier aggregation or multi-connectivity to provide a higher data rate for the UE 110. Multiple wireless links 130 from multiple base stations 120 may be configured for Coordinated Multipoint (COMP) communication with the UE 110.

The base stations 120 are collectively a Radio Access Network 140 (e.g., RAN, Evolved Universal Terrestrial Radio Access Network, E-UTRAN, 5G NR RAN, NR RAN). The base stations 121 and 122 in the RAN 140 are connected to a core network 150. The base stations 121 and 122 connect, at 102 and 104 respectively, to the core network 150 through an NG2 interface for control-plane signaling and using an NG3 interface for user-plane data communications when connecting to a 5G core network, or using an SI interface for control-plane signaling and user-plane data communications when connecting to an Evolved Packet Core (EPC) network. The base stations 121 and 122 can communicate using an Xn Application Protocol (XnAP) through an Xn interface, or using an X2 Application Protocol (X2AP) through an X2 interface, at 106, to exchange user-plane and control-plane data. The user equipment 110 may connect, via the core network 150, to public networks, such as the Internet 160, to interact with a remote service 170.

### Example Devices

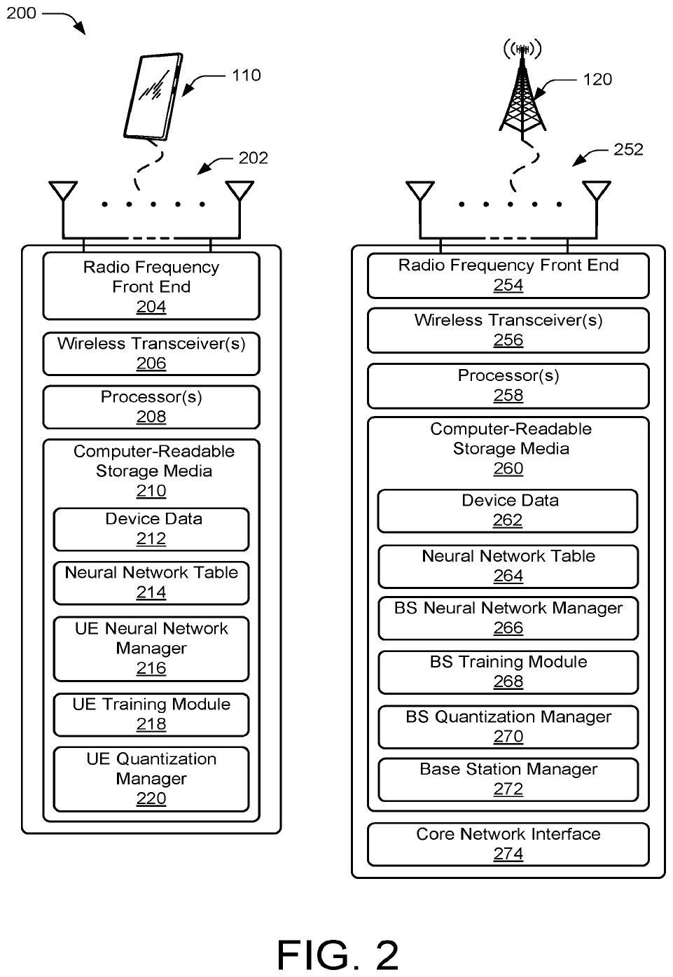

FIG. 2 illustrates an example device diagram 200 of the UE 110 and one of the base stations 120 that can implement various aspects of quantized ML configuration information. The UE 110 and the base station 120 may include additional functions and interfaces that are omitted from FIG. 2 for the sake of clarity.

The UE 110 includes antenna array 202, a radio frequency front end 204 (RF front end 204), and one or more wireless transceiver 206 (e.g., an LTE transceiver, a 5G NR transceiver, and/or a 6G transceiver) for communicating with the base station 120 in the RAN 140. The RF front end 204 of the UE 110 can couple or connect the wireless transceiver 206 to the antenna array 202 to facilitate various types of wireless communication. The antenna array 202 of the UE 110 may include an array of multiple antennas that are configured in a manner similar to or different from each other. The antenna array 202 and the RF front end 204 can be tuned to, and/or be tunable to, one or more frequency bands defined by the 3GPP LTE communication standards, 5G NR communication standards, 6G communication standards, and/or various satellite frequency bands, such as the L-band (1-2 Gigahertz (GHz)), the S-band (2-4 GHz), the C-band (4-8 GHz), the X-band (8-12 GHz), the Ku-band (12-18 GHz), K-band (18-27 GHz), and/or the Ka-band (27-40 GHz), and implemented by the wireless transceiver 206. In some aspects, the satellite frequency bands overlap with the 3GPP LTE-defined, 5G NR-defined, and/or 6G-defined frequency bands. Additionally, the antenna array 202, the RF front end 204, and/or the wireless transceiver 206 may be configured to support beamforming for the transmission and reception of communications with the base station 120. By way of example and not limitation, the antenna array 202 and the RF front end 204 can be implemented for operation in sub-gigahertz (GHz) bands, sub-6 GHz bands, and/or above 6 GHz bands that are defined by the 3GPP LTE, 5G NR, 6G communication standards, and/or satellite communications (e.g., satellite frequency bands).

The UE 110 also includes one or more processor(s) 208 and computer-readable storage media 210 (CRM 210). The processor(s) 208 may be single-core processor(s) or multiple-core processor(s) composed of a variety of materials, for example, silicon, polysilicon, high-K dielectric, copper, and so on. The computer-readable storage media described herein excludes propagating signals. CRM 210 may include any suitable memory or storage device such as random-access memory (RAM), static RAM (SRAM), dynamic RAM (DRAM), non-volatile RAM (NVRAM), read-only memory (ROM), or Flash memory useable to store device data 212 of the UE 110. The device data 212 can include user data, sensor data, control data, automation data, multimedia data, ML quantization codebooks, applications, and/or an operating system of the UE 110, some of which are executable by the processor(s) 208 to enable transmission and/or reception of user-plane data, transmission and/or reception of control-plane information, and user interaction with the UE 110.

In aspects, the CRM 210 includes a neural network table 214 that stores various architecture and/or parameter configurations that form a neural network, such as, by way of example and not of limitation, parameters that specify a fully connected neural network architecture, a convolutional neural network architecture, a recurrent neural network architecture, a number of connected hidden neural network layers, an input layer architecture, an output layer architecture, a number of nodes utilized by the neural network, coefficients (e.g., weights and biases) utilized by the neural network, kernel parameters, a number of filters utilized by the neural network, strides/pooling configurations utilized by the neural network, an activation function of each neural network layer, interconnections between neural network layers, neural network layers to skip, and so forth. Accordingly, the neural network table 214 includes any combination of neural network formation configuration elements (NN formation configuration elements), such as architecture and/or parameter configurations, that can be used to create a neural network formation configuration (NN formation configuration). Generally, a NN formation configuration includes a combination of one or more NN formation configuration elements that define and/or form a DNN. In some aspects, a single index value of the neural network table 214 maps to a single NN formation configuration element (e.g., a 1:1 correspondence). Alternatively, or additionally, a single index value of the neural network table 214 maps to a NN formation configuration (e.g., a combination of NN formation configuration elements). In some implementations, the neural network table includes input characteristics for each NN formation configuration element and/or NN formation configuration, where the input characteristics describe properties about the training data used to generate the NN formation configuration element and/or NN formation configuration as further described. In aspects, a machine-learning configuration (ML configuration) corresponds to an NN formation configuration.

The CRM 210 may also include a user equipment neural network manager 216 (UE neural network manager 216). Alternatively, or additionally, the UE neural network manager 216 may be implemented in whole or part as hardware logic or circuitry integrated with or separate from other components of the user equipment 110. The UE neural network manager 216 accesses the neural network table 214, such as by way of an index value, and forms a DNN using the NN formation configuration elements specified by a NN formation configuration, such as a modulation DNN and/or a demodulation DNN. This includes updating the DNN with any combination of architectural changes and/or parameter changes to the DNN as further described, such as a small change to the DNN that involves updating parameters and/or a large change that reconfigures node and/or layer connections of the DNN. In some aspects, the UE neural network manager 216 forwards ML configuration updates (e.g., generated by a training module), to the base station 120.

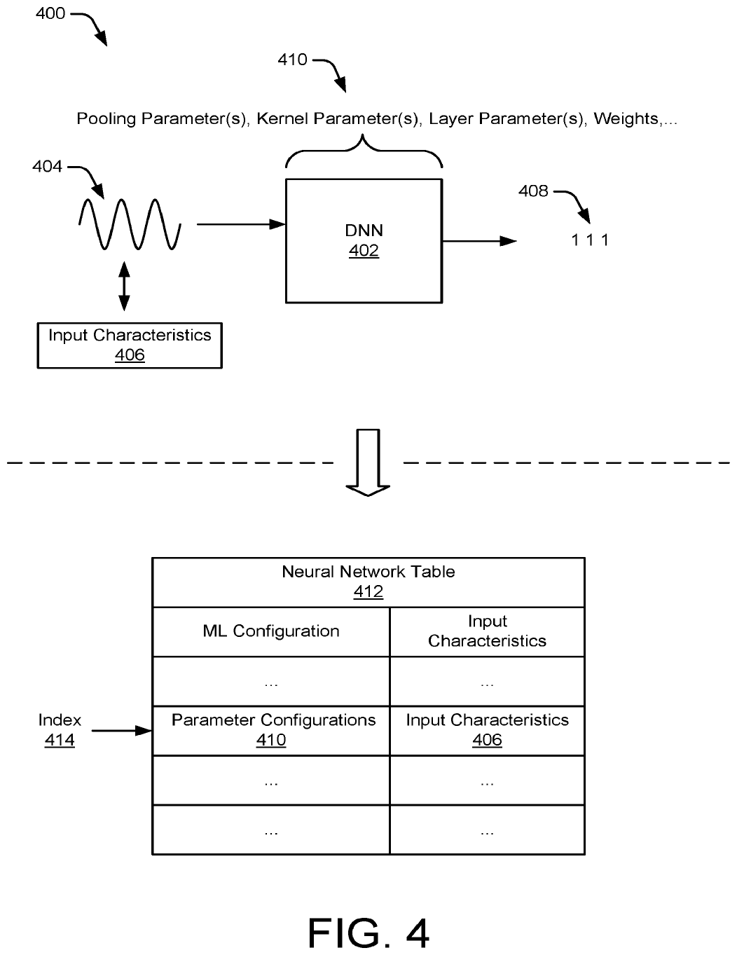

The CRM 210 includes a user equipment training module 218 (UE training module 218). Alternatively, or additionally, the UE training module 218 may be implemented in whole or part as hardware logic or circuitry integrated with or separate from other components of the user equipment 110. The UE training module 218 teaches and/or trains DNNs using known input data, such as that described with reference to FIG. 4, and/or feedback generated by the DNNs (e.g., bit error information, signal quality measurements, link quality measurements) while processing wireless communications. Accordingly, the UE training module 218 may train DNN(s) offline (e.g., while the DNN is not actively engaged in processing wireless communications) and/or online (e.g., while the DNN is actively engaged in processing wireless communications).

The CRM 210 includes a user equipment quantization manager 220 (UE quantization manager 220). The UE quantization manager 220 may be implemented in whole or part as hardware logic or circuitry integrated with or separate from other components of the user equipment 110. The UE quantization manager 220 receives an indication of a quantization configuration and processes ML configuration information based on the indicated quantization format, such as using the quantization configuration to generate ML configuration information and/or using the quantization configuration to recover ML configuration information. As one example, the UE quantization manager 220 uses the quantization configuration to recover ML configuration information from quantized ML configuration information received over the wireless network. To illustrate, the UE quantization manager 220 recovers ML configuration information from quantized ML configuration information based on any combination of quantization formats (e.g., scalar quantization, vector quantization, a scaling quantization format) specified in the quantization configuration. The UE quantization manager 220, for instance, uses different layer-based quantization configurations to recover different layers of a DNN (e.g., uses a first quantization configuration to recover a first ML configuration for first layer of a DNN, a second quantization configuration to recover a second ML configuration for a second layer of the DNN, and so forth), where the quantization configuration specifies different quantization formats for the different layers. The quantization configuration may specify layer-based quantization configurations (e.g., different quantization configurations for different layers) for only some of the layers in the DNN and may exclude layer-based quantization configurations for other layers in the DNN, such as hidden layers.

As another example, the UE quantization manager 220 generates quantized ML configuration information using the quantization format in a reciprocal manner to recovering ML configuration information. To illustrate, assume the UE 110 locally generates gradient information that specifies an update to a UE-side DNN. Using the gradient information as input, the UE quantization manager 3220 uses the quantization configuration specified by the base station 120 to quantize the gradient information, which is then sent to the base station 120 as quantized ML configuration information. Alternatively or additionally, the UE quantization manager 220 uses the quantization configuration to quantize ML configuration information for the different layers in a reciprocal manner to recovering the different ML configuration information for the different layers.

The device diagram for the base station 120, shown in FIG. 2, includes a single network node (e.g., a gNode B). The functionality of the base station 120 may be distributed across multiple network nodes or devices and may be distributed in any fashion suitable to perform the functions described herein. The nomenclature for this distributed base station functionality varies and includes terms such as Central Unit (CU), Distributed Unit (DU), Baseband Unit (BBU), Remote Radio Head (RRH), Radio Unit (RU), and/or Remote Radio Unit (RRU). The base station 120 includes antenna array 252, a radio frequency front end 254 (RF front end 254), one or more wireless transceivers 256 (e.g., one or more LTE transceivers, one or more 5G NR transceivers, and/or one or more 6G transceivers) for communicating with the UE 110. The RF front end 254 of the base station 120 can couple or connect the wireless transceivers 256 to the antenna array 252 to facilitate various types of wireless communication. The antenna array 252 of the base station 120 may include an array of multiple antennas that are configured in a manner similar to, or different from, each other. The antenna array 252 and the RF front end 254 can be tuned to, and/or be tunable to, one or more frequency bands defined by the 3GPP LTE, 5G NR, 6G communication standards, and/or various satellite frequency bands, and implemented by the wireless transceivers 256. Additionally, the antenna array 252, the RF front end 254, and the wireless transceivers 256 may be configured to support beamforming (e.g., Massive multiple-input, multiple-output (Massive-MIMO)) for the transmission and reception of communications with the UE 110.

The base station 120 also includes processor(s) 258 and computer-readable storage media 260 (CRM 260). The processor 258 may be a single-core processor or a multiple-core processor composed of a variety of materials, for example, silicon, polysilicon, high-K dielectric, copper, and so on. CRM 260 may include any suitable memory or storage device such as random-access memory (RAM), static RAM (SRAM), dynamic RAM (DRAM), non-volatile RAM (NVRAM), read-only memory (ROM), or Flash memory useable to store device data 262 of the base station 120. The device data 262 can include network scheduling data, radio resource management data, beamforming codebooks, applications, and/or an operating system of the base station 120, which are executable by processor(s) 258 to enable communication with the UE 110.

The CRM 260 includes a neural network table 264 that stores multiple different NN formation configuration elements and/or NN formation configurations (e.g., ML configurations), where the NN formation configuration elements and/or NN formation configurations define various architecture and/or parameters for a DNN as further described with reference to FIG. 4. In some implementations, the neural network table includes input characteristics for each NN formation configuration element and/or NN formation configuration, where the input characteristics describe properties about the training data used to generate the NN formation configuration element and/or NN formation configuration. For instance, the input characteristics include, by way of example and not of limitation, an estimated UE location, multiple-input, multiple-output (MIMO) antenna configurations, power information, signal-to-interference-plus-noise ratio (SINR) information, channel quality indicator (CQI) information, channel state information (CSI), Doppler feedback, frequency bands, BLock Error Rate (BLER), Quality of Service (QOS), Hybrid Automatic Repeat reQuest (HARQ) information (e.g., first transmission error rate, second transmission error rate, maximum retransmissions), latency, Radio Link Control (RLC), Automatic Repeat reQuest (ARQ) metrics, received signal strength (RSS), uplink SINR, timing measurements, error metrics, UE capabilities, BS capabilities, power mode, Internet Protocol (IP) layer throughput, end2end latency, end2end packet loss ratio, etc. Accordingly, the input characteristics include, at times, Layer 1, Layer 2, and/or Layer 3 metrics. In some implementations, a single index value of the neural network table 264 maps to a single NN formation configuration element (e.g., a 1:1 correspondence). Alternatively, or additionally, a single index value of the neural network table 264 maps to a NN formation configuration (e.g., a combination of NN formation configuration elements).

CRM 260 also includes a base station neural network manager 266 (BS neural network manager 266). Alternatively, or additionally, the BS neural network manager 266 may be implemented in whole or part as hardware logic or circuitry integrated with or separate from other components of the base station 120. In at least some aspects, the BS neural network manager 266 selects the NN formation configurations utilized by the base station 120 and/or UE 110 to configure deep neural networks for processing wireless communications, such as by selecting a combination of NN formation configuration elements to form base station-side (BS-side) DNNs for processing downlink and/or uplink communications and/or NN formation configurations to form user equipment-side (UE-side) DNNs for processing downlink and/or uplink communications. In some aspects, the BS neural network manager 266 indicates a selected NN formation configuration (e.g., an ML configuration) to a quantization manager for quantization.

The CRM 260 includes a base station training module 268 (BS training module 268). Alternatively, or additionally, the BS training module 268 may be implemented in whole or part as hardware logic or circuitry integrated with or separate from other components of the base station 120. In aspects, the BS training module 268 teaches and/or trains DNNs using known input data and/or using feedback generated while the DNNs process wireless communications. Accordingly, the BS training module 268 may train DNN(s) offline (e.g., while the DNN is not actively engaged in processing wireless communications) and/or online (e.g., while the DNN is actively engaged in processing wireless communications).

In aspects, the BS training module 268 extracts learned parameter configurations from the DNN as further described with reference to FIG. 4. The BS training module 268 may then use the extracted learned parameter configurations to create and/or update the neural network table 264. The extracted parameter configurations include any combination of information that defines the behavior of a neural network, such as node connections, coefficients, active layers, weights, biases, pooling, etc.

The CRM 260 includes a base station quantization manager 270 (BS quantization manager 270). The BS quantization manager 270 may be implemented in whole or part as hardware logic or circuitry integrated with or separate from other components of the base station 120. In aspects, the BS quantization manager 270 selects a quantization configuration for quantizing ML configuration information (e.g., ML configurations, ML configuration updates). As one example, the BS quantization manager 270 selects, as the quantization configuration, one or more quantization formats based on quantization formats supported by the UE 110 and directs the base station 120 to indicate the quantization configuration to the UE 110. In aspects, the BS quantization manager 270 selects the quantization configuration based on layers within a DNN, such as layer-based quantization configurations based on properties about each layer. To illustrate, the BS quantization manager 270 selects a scalar quantization format for a first layer of the DNN based on a first number of nodes utilized by the first layer and a vector quantization format for a second layer of the DNN based on a second number of nodes utilized by the second layer. As another example, the BS quantization manager 270 selects the quantization configuration based on phases of optimization implemented at each layer (e.g., fewer bits for a first layer, more bits for a second layer).

In aspects, the BS quantization manager 270 generates quantized ML configuration information using the quantization configuration. For example, the BS quantization manager 270 receives an indication of an ML configuration (or an ML configuration update) from the BS neural network manager 266 and selects a vector from a vector quantization codebook that maps to ML configuration.

Alternatively or additionally, the BS quantization manager 270 recovers ML configuration information using the quantization configuration. To illustrate, and in a reciprocal manner, the BS quantization manager 270 receives an index value that maps to an entry of a vector quantization codebook and extracts the ML configuration (or the ML configuration update) from the vector quantization codebook.

Generating quantized ML configuration information and/or recovering ML configuration information from quantized ML configuration information may include using any combination of quantization formats (e.g., scalar quantization, vector quantization, a scaling quantization format) for one or more layers of a DNN. In aspects, this includes using different quantization configurations and/or quantization formats for different layers, such as a first quantization configuration for a first layer (or first group of layers) in a DNN, a second quantization configuration for a second layer (or a second group of layers) in the DNN, and so forth.

CRM 260 also includes a base station manager 272. Alternatively, or additionally, the base station manager 272 may be implemented in whole or part as hardware logic or circuitry integrated with or separate from other components of the base station 120. In at least some aspects, the base station manager 272 configures the wireless transceiver(s) 256 for communication with the UE 110.

The base station 120 also includes a core network interface 274 that the base station manager 272 configures to exchange user-plane data, control-plane information, and/or other data/information with core network functions and/or entities. As one example, the base station 120 uses the core network interface 274 to communicate with the core network 150 of FIG. 1.

### Deep Neural Networks in Wireless Communications

Generally, a DNN corresponds to groups of connected nodes that are organized into three or more layers, where the DNN dynamically modifies the behavior and/or resulting output of the DNN algorithms using training and feedback. For example, a DNN identifies patterns in data through training and feedback and generates new logic that modifies the machine-learning algorithm (implemented as the DNN) to predict or identify these patterns in new (future) data. The connected nodes between layers are configurable in a variety of ways, such as a partially connected configuration where a first subset of nodes in a first layer are connected with a second subset of nodes in a second layer, or a fully connected configuration where each node in a first layer is connected to each node in a second layer, etc. The nodes can use a variety of algorithms and/or analysis to generate output information based upon adaptive learning, such as single linear regression, multiple linear regression, logistic regression, step-wise regression, binary classification, multiclass classification, multi-variate adaptive regression splines, locally estimated scatterplot smoothing, and so forth. At times, the algorithm(s) include weights and/or coefficients that change based on adaptive learning. Thus, the weights and/or coefficients reflect information learned by the DNN.

A DNN can also employ a variety of architectures that determine what nodes within the corresponding neural network are connected, how data is advanced and/or retained in the neural network, what weights and coefficients are used to process the input data, how the data is processed, and so forth. These various factors collectively describe a NN formation configuration (also referred to as a machine-learning (ML) configuration). To illustrate, a recurrent neural network (RNN), such as a long short-term memory (LSTM) neural network, forms cycles between node connections in order to retain information from a previous portion of an input data sequence. The recurrent neural network then uses the retained information for a subsequent portion of the input data sequence. As another example, a feed-forward neural network passes information to forward connections without forming cycles to retain information. While described in the context of node connections, it is to be appreciated that the NN formation configuration can include a variety of parameter configurations that influence how the neural network processes input data.

An NN formation configuration used to form a DNN can be characterized by various architecture and/or parameter configurations. To illustrate, consider an example in which the DNN implements a convolutional neural network. Generally, a convolutional neural network corresponds to a type of DNN in which the layers process data using convolutional operations to filter the input data. Accordingly, the convolutional NN formation configuration can be characterized with, by way of example and not of limitation, pooling parameter(s) (e.g., specifying pooling layers to reduce the dimensions of input data), kernel parameter(s) (e.g., a filter size and/or kernel type to use in processing input data), weights (e.g., biases used to classify input data), and/or layer parameter(s) (e.g., layer connections and/or layer types). While described in the context of pooling parameters, kernel parameters, weight parameters, and layer parameters, other parameter configurations can be used to form a DNN. Accordingly, an NN formation configuration (e.g., an ML configuration) can include any other type of parameter that can be applied to a DNN that influences how the DNN processes input data to generate output data.

FIG. 3 illustrates an example environment 300 in which devices (e.g., the base station 120, the UE 110) use DNNs for performing transmitter and/or receiver processing chain operations in accordance with aspects of quantized ML configuration information. In the environment 300, the BS neural network manager 266 of the base station 120 includes and/or manages a downlink (DL) wireless communications processing chain 302 (downlink processing chain 302) for processing downlink communications to the UE 110, where the downlink processing chain 302 corresponds to a transmitter processing chain. To illustrate, the BS neural network manager 266 selects one or more default ML configurations or one or more specific ML configurations (e.g., based on current downlink channel conditions as further described) and forms the DNNs 304 using the ML configurations. In aspects, the DNN(s) 304 perform some or all functionality of a (wireless communications) transmitter processing chain, such as receiving binary data as an input, encoding the binary data, generating a digital modulated baseband or intermediate frequency (IF) signal using the encoded data, performing MIMO transmission operations (e.g., antenna selection, MIMO precoding, MIMO spatial multiplexing, MIMO diversity coding processing), and/or generating an upconverted signal (e.g., a digital representation) that feeds a digital-to-analog converter (DAC), which feeds an antenna array for a downlink transmission to the UE 110.

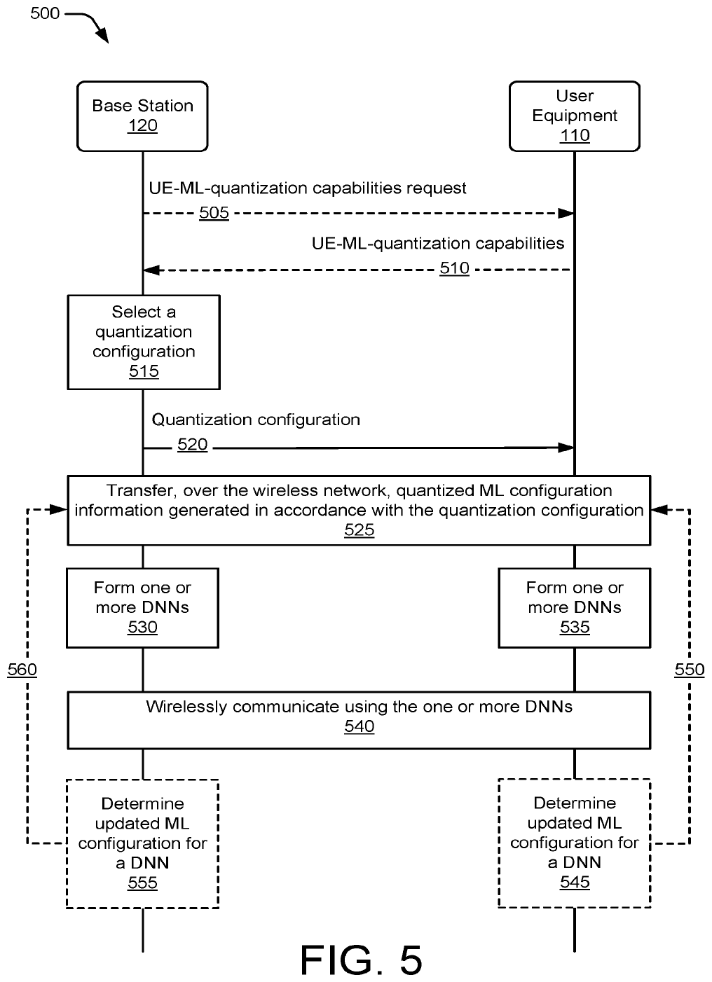

Similarly, the UE neural network manager 216 of the UE 110 includes and/or manages a downlink wireless communications processing chain 306 (downlink processing chain 306) for processing downlink communications from the base station 120, where the downlink processing chain 306 corresponds to a receiver processing chain. To illustrate, the UE neural network manager 216 forms one or more deep neural network(s) 308 (DNNs 308) using an ML configuration indicated by the base station 120 and/or using an ML configuration selected by the UE neural network manager 216. This can include using a quantization configuration indicated by the base station 120, where the UE quantization manager 220 (not shown in FIG. 3) recovers the ML configuration based on a quantization format as further described with reference to FIG. 5. In aspects, the DNNs 308 perform some or all functionality of a (wireless communications) receiver processing chain, such as processing that is complementary to that performed by the BS DL processing chain (e.g., a down-conversion stage, a demodulating stage, a decoding stage). To illustrate, the DNNs 308 can perform any combination of demodulating/extracting data embedded on the receive (RX) signal, recovering control information, recovering binary data, correcting for data errors based on forward error correction applied at the transmitter block, extracting payload data from frames and/or slots, and so forth.

The UE 110 also includes an uplink (UL) wireless communications processing chain 310 (uplink processing chain 310) that processes uplink communications using one or more deep neural networks 312 (DNN(s) 312) configured and/or formed by the UE neural network manager 216, where the uplink processing chain 310 corresponds to a transmitter processing chain. To illustrate, and as described with reference to the DNNs 304, the DNNs 312 perform some or all (uplink) transmitter chain processing operations for generating an uplink transmission directed to the base station 120.

The base station 120 includes an uplink wireless communications processing chain 314 (uplink processing chain 314) that processes (received) uplink communications using one or more deep neural networks 316 (DNN(s) 316) managed and/or formed by the BS neural network manager 266. The DNNs 316 perform complementary processing (e.g., receiver chain processing operations as described with reference to the DNNs 308) to that performed by the UE uplink processing chain 310.

### Machine-Learning Configurations

FIG. 4 illustrates an example 400 that describes aspects of generating ML configurations (e.g., NN formation configurations) in accordance with aspects of quantized ML configuration information. At times, various aspects of the example 400 are implemented by any combination of the UE neural network manager 216, the UE training module 218, the BS neural network manager 266, and/or the BS training module 268 of FIG. 2.

The upper portion of FIG. 4 includes a DNN 402 that represents any suitable DNN used to implement portions or all of a wireless communications processing chain. In aspects, a neural network manager generates different ML configurations for forming DNNs that perform portions of a wireless communications processing chain, where an ML configuration may specify one or more NN formation configuration elements. Training data 404 represents an example input to the DNN 402, such as data corresponding to a digital, modulated base band signal for any combination of: a downlink communication, an uplink communication, a MIMO and/or operating configuration, and/or a transmission environment. In some implementations, the training module generates the training data mathematically or accesses a file that stores the training data. Other times, the training module obtains real-world communications data. Thus, the training module can train the DNN 402 using mathematically generated data, static data, and/or real-world data. Some implementations generate input characteristics 406 that describe various qualities of the training data, such as an operating configuration, transmission channel metrics, MIMO configurations, UE capabilities, UE location, modulation schemes, coding schemes, and so forth.

The DNN 402 analyzes the training data and generates an output 408 represented here as binary data. However, in other aspects, such as when the training data corresponds to binary data, the output 408 corresponds to a digital, modulated baseband or IF signal. Some implementations iteratively train the DNN 402 using the same set of training data and/or additional training data that has the same input characteristics to improve the accuracy of the machine-learning module. During training, the machine-learning module modifies some or all of the architecture and/or parameter configurations of a neural network included in the machine-learning module, such as node connections, coefficients, kernel sizes, etc.

In aspects, the training module extracts the architecture and/or parameter configurations 410 of the DNN 402 (e.g., pooling parameter(s), kernel parameter(s), layer parameter(s), weights), such as when the training module identifies that the accuracy meets or exceeds a desired threshold, the training process meets or exceeds an iteration number, and so forth. The extracted architecture and/or parameter configurations from the DNN 402 correspond to an NN formation configuration, NN formation configuration element(s), an ML configuration, and/or updates to an ML configuration. The architecture and/or parameter configurations can include any combination of fixed architecture and/or parameter configurations, and/or variable architectures and/or parameter configurations.

The lower portion of FIG. 4 includes a neural network table 412 that represents a collection of ML configurations (e.g., NN formation configuration elements), such as the neural network table 214 and/or the neural network table 264 of FIG. 2. The neural network table 412 stores various combinations of architecture configurations, parameter configurations, and input characteristics, but alternative implementations omit the input characteristics from the table. Various implementations update and/or maintain the NN formation configuration elements and/or the input characteristics as the DNN learns additional information. For example, at index 414, the neural network manager and/or the training module updates neural network table 412 to include architecture and/or parameter configurations 410 generated by the DNN 402 while analyzing the training data 404. At a later point in time, a neural network manager (e.g., the UE neural network manager 216, the BS neural network manager 266) selects one or more ML configurations from the neural network table 412 by matching the input characteristics to a current operating environment and/or configuration, such as by matching the input characteristics to current channel conditions and/or a MIMO configuration (e.g., antenna selection).

### Quantized ML Configurations

In aspects, wireless communication devices implement a wireless communications processing chain (e.g., a transmitter processing chain and/or a receiver processing chain) using DNNs to perform some or all processing chain operations. The inclusion of a DNN within a wireless communications processing chain provides flexibility for modifying how transmissions are generated and/or received in response to changes in an operating environment. To illustrate, some aspects dynamically modify the DNN to generate a transmission with properties (e.g., carrier frequency, modulation scheme, beam direction, MIMO antenna selection) that mitigate problems in the current transmission channel. Oftentimes, a first wireless communication device communicates ML configuration information (e.g., an ML configuration, and ML configuration update) to a second wireless communication device using a wireless network. As one example, a base station selects and/or communicates an initial UE-side ML configuration that forms a UE-side DNN for processing wireless communications. This can include the base station selecting a common UE-side ML configuration for a group of UEs. As another example, the UE (or each UE in a group of UEs) trains the UE-side DNN and transmits ML configuration updates (e.g., learned weights, learned biases, learned gradients) to the base station. Transmitting the ML configuration information can consume large quantities of air interface resources and/or drain power resources of a device. It is therefore desirable to increase the efficiency of how devices communicate the ML configuration information to increase the efficiency of how corresponding resources of the wireless network are used, reduce wasted resources, and/or preserve a battery life of the device.

FIG. 5 illustrates an example control signaling transaction diagram 500 between a base station and a user equipment in accordance with one or more aspects of communicating quantized ML configuration information. In implementations, the signaling may be performed by any combination of the base station 120 (FIG. 1) and the UE 110 (FIG. 1) using elements of FIGS. 1-4. While the diagram 500 includes a single UE (e.g., UE 110), various signaling shown can be performed with multiple UEs, such as when performing federated learning techniques. The diagram 500 denotes optional transactions using dashed lines.

As illustrated, at 505, the base station 120 optionally requests UE-ML-quantization capabilities from the UE 110. For instance, the base station 120 sends a radio resource control (RRC) message that includes a UECapabilityEnquiry information element (IE) that indicates a request for UE-ML-quantization capabilities from the UE 110. To illustrate, the base station 120 configures the UECapabilityEnquiry IE to request the UE-ML-quantization capabilities, such as through the inclusion of a toggle field, a Boolean value, an enumerated value, and so forth. In one example, the base station 120 sends the UECapabilityEnquiry IE in the RRC message during a registration process. In aspects, the base station 120 requests UE-ML-quantization capabilities from multiple UEs.

The base station 120 may generically request UE-ML-quantization capabilities without explicitly specifying any quantization formats in the request, such as by setting a toggle field. Alternatively, the base station 120 explicitly requests information about whether the UE 110 supports specific quantization formats, such as a vector quantization format, a scalar quantization format, and/or a scalar quantization format. A vector quantization format quantizes ML configuration information into a vector representation. To illustrate, consider a quantization codebook that includes multiple entries, where each entry includes a respective vector of ML parameters, such as a set of ML coefficients (e.g., weights, biases) that correspond to a set of nodes in a DNN and/or a set of gradient values. The vector quantization format communicates, as the quantized ML configuration information, an index value that maps to an entry in the quantization codebook that corresponds to a vector representative of the ML configuration information. Selecting the vector representation may include using a distance metric as further described.

A scalar quantization format quantizes ML configuration information using a fixed number of bits, such as 8-bit or 16-bit quantization. In other words, the scalar quantization format quantizes the ML configuration information using a fixed number of bits for each individual ML parameter. In some aspects, a quantization codebook represents a vector using scalar values.

A sparsity quantization format quantizes ML configuration information by excluding information identified as a zero value (e.g., values less than a threshold value) and/or by only including information identified as a non-zero value (e.g., values with absolute values being equal to or greater than a threshold value) in the quantized representation of the ML configuration information (e.g., a quantized ML configuration, a quantized ML configuration update). To illustrate, a device that communicates quantized ML configuration information using a sparsity quantization format only communicates the non-zero values, sometimes with indices or addresses of the non-zero values.

At 510, the UE 110 optionally communicates UE-ML-quantization capabilities supported by the UE to the base station 120. To illustrate, the UE 110 sends an RRC message that includes the quantization formats supported by the UE. This can include the UE specifying any combination of supported UE-ML-quantization capabilities, such as supported quantization formats (e.g., a scalar quantization format, a vector quantization format, or both), supported quantization codebooks, whether the UE supports updating the quantization codebooks, fixed-point quantization formats, floating-point quantization formats, and so forth. The UE 110 may communicate the UE-ML-quantization capabilities in response to receiving the UECapabilityEnquiry IE as described at 505 or as part of other processes in which the UE communicates capabilities. In some aspects, the UE 110 indicates a supported codebook size and/or a supported codebook-adaptability mode (e.g., whether the UE 110 supports updating quantization codebooks).

At 515, the base station 120 selects a quantization configuration. To illustrate, the base station 120 selects one or more quantization formats for quantizing ML configuration information. In some aspects, the base station 120 selects a default quantization configuration, such as a quantization configuration specified by communication standards, for broadcasting and/or multicasting quantized ML configuration information to multiple UEs. Alternatively, the base station 120 selects the quantization configuration based on the UE-ML-quantization capabilities indicated at 510. In some aspects, the base station 120 selects a common quantization configuration for a group of UEs selected for participating in federated learning, which may include the base station 120 analyzing multiple sets of UE-ML-quantization capabilities.

As one example, when the UE 110 only indicates support for a vector quantization format (and does not indicate support for a scalar quantization format), the base station 120 selects, as the quantization configuration, the vector quantization format. The base station 120 may also select a configuration for selected quantization formats in the quantization configuration. To illustrate, in selecting a scalar quantization format, the base station 120 may also select a number of bits to use for the scalar quantization format. As another example, the base station 120 may select a scaling factor value for scalar representations and/or normalized vectors. This may include selecting one or more codebook-scaling factors, where each codebook-scaling factor corresponds to a respective quantization codebook.

In some aspects, the base station 120 selects, as part of the quantization configuration, one or more quantization codebooks. As an example, the base station 120 selects the quantization codebook(s) based on a codebook size supported (and indicated) by the UE. Alternatively or additionally, the base station 120 enables or disables, as part of the quantization configuration, a codebook-adaptability mode that enables or disables updating quantization codebooks (e.g., based on learned ML configurations and/or ML configuration updates).

In some aspects, the base station 120 selects, as part of the quantization configuration, a fixed-point format or a floating-point format. The base station 120 may additionally specify, in the quantization configuration, configurations for these formats, such as by specifying exponent and mantissa representations.

In some aspects, the base station 120 selects, as part of the quantization configuration, the sparsity quantization format. This may include the base station selecting a first threshold value used to identify zero values and/or selecting a second threshold value used to identify non-zero values (e.g., when absolute values are above the second threshold). Thus, devices quantizing ML configuration information using the sparsity quantization format use the threshold value(s) specified in the quantization configuration to identify zero values and non-zero values.

In some aspects, the base station 120 selects, as part of the quantization configuration, quantization codebooks. This may include the base station selecting one or more quantization codebooks that include weight vectors, bias vectors, and/or gradient vectors. Alternatively or additionally, the base station 120 selects a complex codebook that stores entries in the complex domain (e.g., the Fourier domain) using a complex numerical format (e.g., polar notation, rectangular coordinates).

In some aspects, the base station 120 selects, as part of the quantization configuration, a distance metric that specifies an acceptable divergence amount for selecting vectors. For instance, to quantize ML configuration information using the vector quantization format, a device selects a representative vector using the distance metric to measure and identify a vector within a quantization codebook within an acceptable divergence amount from the ML configuration. This can include the base station 120 selecting a distance metric format, such as a Euclidean distance format, a cosine distance format, or an L1/l-infinity norm distance format.

In selecting the quantization configuration, the base station 120 may select different quantization configurations for different layers. For example, assume the base station 120 identifies a total number of bits to use for transmitting quantized ML configuration information, and determines, based on the total number of bits, to select different quantization configurations for the DNN layers that minimize a respective number of bits used for establishing or updating each layer. In response to determining to select different quantization configurations for the different layers, the base station 120 selects, for a first layer of a DNN, a first quantization configuration that specifies a first number of bits for quantizing ML configuration information associated with the first layer and a second quantization configuration for a second layer of the DNN that specifies a second number of bits for quantizing ML configuration information associated with the second layer. While described in terms of number of bits, the layer-based quantization configurations can specify any combination of information (e.g., quantization codebooks, scalar quantization format, vector quantization format, sparsity quantization format, distance metrics). The base station 120 may select quantization configurations for groups of layers. As an example, the base station selects a first quantization configuration for a first group of layers in a DNN, a second quantization configuration for a second group of layers in the DNN, and so forth. Alternatively, the base station selects a common quantization configuration for all layers of the DNN.

In some aspects, the base station 120 selects the quantization configuration based on a neural network size (e.g., a number of layers included in a DNN, a number of nodes in a layer). To illustrate, the base station 120 selects, as part of the quantization configuration, the scalar quantization format when the number of nodes in a layer of a DNN (or a number of layers in the DNN) is less than a threshold value. Alternatively, the base station 120 selects, as part of the quantization configuration, the vector quantization format when the number of nodes (or the number of layers) is equal to or greater than the threshold value.

At 520, the base station 120 communicates the quantization configuration to the UE 110. As one example, the base station 120 unicasts the quantization configuration to the UE 110. As another example, the base station 120 broadcasts or multicasts the quantization configuration to the UE 110 and other UEs. In some aspects, the base station 120 communicates a common quantization configuration to a group of UEs (e.g., for federated learning by the base station). However, the base station 120 may alternatively select different quantization configurations for the UEs included in the group of UEs.

At 525, the base station 120 and the UE 110 transfer quantized ML configuration information (e.g., quantized ML configurations, quantized ML configuration updates) to one another, where the quantized ML configuration information is generated in accordance with the quantization configuration (e.g., following the quantization formats specified by the quantization configuration). As one example, the base station 120 transmits, and the UE 110 receives, quantized ML configuration information that corresponds to an initial and/or common UE-side ML configuration for forming a UE-side DNN in a wireless communications processing chain. To illustrate, assuming the quantization configuration specifies a vector quantization format and/or a quantization codebook, the base station 120 indicates an index value that maps to an entry of the specified quantization codebook that corresponds to a vector representation of the UE-side ML configuration. The UE 110 may then use the quantization configuration to recover the ML configuration information (e.g., extract weights and biases from a vector codebook) from the quantized ML configuration information. In some aspects, the UE 110 applies an ML configuration to a DNN using the quantization configuration (e.g., applying a scalar value to the quantized ML configuration information).

As another example, the UE 110 transmits, and the base station receives, quantized ML configuration information, such as a UE-selected ML configuration and/or quantized ML configuration updates, following the quantization format(s) specified by the quantization configuration to quantize the ML configuration information. The base station 120 uses the quantization configuration to recover the ML configuration information, which may cause the base station 120 to update a BS-side DNN and/or identify updates for a UE-side DNN using federated learning techniques as further described at 555 to improve transmission and reception of wireless signals processed by the BS-side DNN and/or the UE-side DNNs.

At 530, the base station 120 forms one or more DNNs, such as a BS-side DNN that processes downlink communications in a transmitter processing chain and/or a BS-side DNN that processes uplink communications in a receiver processing chain. Similarly, at 535, the UE 110 forms one or more DNNs, such as a UE-side DNN that processes downlink communications in a receiver processing chain and/or a UE-side DNN that processes uplink communications in a transmitter processing chain. In response to forming the DNNs at 530 and/or at 535, the base station 120 and the UE 110 wirelessly communicate using the one or more DNNs, such as in a manner as described with reference to FIG. 3. Forming the DNNs at 530 and at 535 can include (a) small adjustments using parameter updates (e.g., coefficients, weights) to tune existing UE-side DNN(s) and/or BS-side DNN(s) based on feedback indicated by the quantized ML configuration information and/or (b) ML architecture changes (e.g., number of layers, layer down-sampling configurations, changing layers to fully convolutional layers, changing layers to partially convolutional layers) to reconfigure the UE-side DNN(s) and/or BS-side DNN(s).

For clarity, the diagram 500 shows both the base station 120 and the UE 110 forming DNNs in wireless communication processing chains, but other implementations may only include one device (e.g., either the UE 110 or the base station 120) forming a DNN. As one example, the base station 120 utilizes conventional processing blocks in a transmitter and/or receiver processing chain (e.g., without DNNs) and the UE 110 forms a complementary receiver and/or transmitter processing chain using DNN(s). As another example, the UE 110 utilizes conventional processing blocks in a transmitter and/or receiver processing chain (e.g., without DNNs) and the base station 120 forms a complementary receiver and/or transmitter processing chain using DNN(s). Accordingly, at 540, wirelessly communicating using the one or more DNNs can include a first device utilizing at least one DNN and a second device utilizing conventional processing blocks.

At 545, the UE 110 optionally determines an updated ML configuration for a DNN. As one example, the UE 110 determines to train a UE-side DNN included in a receiver processing chain based on a bit error value exceeding a threshold value and extracts an updated ML configuration from the training as described with reference to FIG. 4. As another example, the UE 110 identifies when an architecture of the UE-side DNN changes and obtains the updated ML configuration that includes the architecture change. In response to determining the updated ML configuration, and as shown at 550, the UE 110 wirelessly communicates quantized ML configuration information (e.g., the quantized ML configuration updates) to the base station 120 using various quantization formats and/or configurations specified by the quantization configuration. As shown in FIG. 5, this may cause the base station 120 to update a corresponding BS-side DNN and/or select an update to federated UE-side DNNs to improve transmission and/or reception of signals in the corresponding wireless network. In some aspects, such as when the base station 120 directs the UE 110 to communicate updates to an initial ML configuration, such as when the base station 120 and the UE 110 participate in federated learning with other UEs, the UE 110 determines the updated ML configuration based on trigger conditions (e.g., periodicity, threshold value of change) specified from the base station 120.

In a similar manner, the base station 120 optionally determines an updated ML configuration for a DNN at 555. To illustrate, the base station 120 determines a common ML configuration update for a UE-side DNN based on federated learning techniques that aggregate ML configurations from multiple UEs. Accordingly, and as shown at 560, the base station 120 communicates quantized ML configuration information (e.g., quantized common ML configuration updates) to the UE 110 using the quantization format.

Quantized ML configuration information reduces an amount of data and/or information used to represent the ML configuration information. Accordingly, devices use less air interface resources of a wireless network to communicate quantized ML configuration information relative to the ML configuration information, which preserves the air interface resources of the wireless network for other tasks. This improves the wireless network's ability to meet changes in demand and/or address changing channel conditions, and subsequently improves the reliability of the services provided by the wireless network. This also reduces power consumption at the devices and preserves battery life.

### Example Methods

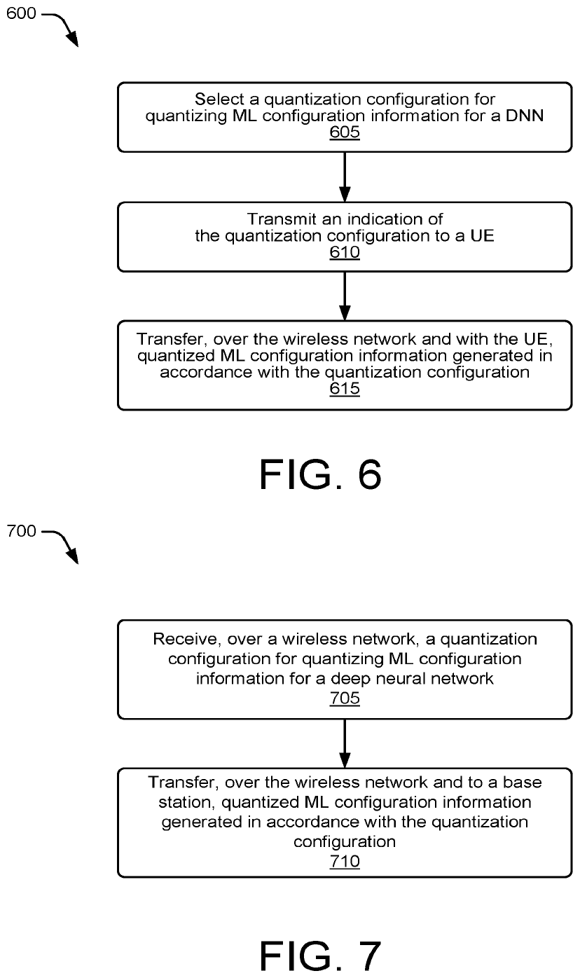

Example methods 600 and 700 are described with reference to FIGS. 6 and 7 in accordance with one or more aspects of quantized ML configuration information. FIG. 6 illustrates an example method 600 for communicating quantized ML configuration information. In aspects, operations of the method 600 are performed by a base station, such as the base station 120.

At 605, a base station selects a quantization configuration for quantizing ML configuration information for a DNN, where the quantization configuration specifies one or more quantization formats associated with quantizing the ML configuration information. To illustrate, and as described at 515 of FIG. 5, the base station (e.g., the base station 120) selects one or more quantization formats and/or configurations of the quantization formats. In some aspects, the base station 120 selects a default quantization configuration, such as a quantization configuration specified by a communication standard. In other aspects, the base station 120 selects the quantization configuration based on UE-ML-quantization capabilities received from one or more UEs. The specified quantization formats may be associated with quantizing ML configuration information and/or with recovering ML configuration information from the quantized ML configuration information.

At 610, the base station transmits an indication of the quantization configuration to a UE. As one example, and as described at 520 of FIG. 5, the base station (e.g., the base station 120) unicasts the quantization configuration to the UE (e.g., the UE 110). As another example, the base station broadcasts or multicasts the quantization configuration to the.

At 615, the base station transfers, over the wireless network and with the UE, quantized ML configuration information generated in accordance with the quantization configuration. For instance, the base station (e.g., the base station 120) generates quantized ML information in accordance with the one or more quantization formats specified by the quantization configuration and transmits the quantized ML configuration information to the UE (e.g., the UE 110) as described at 525 of FIG. 5. Alternatively or additionally, the base station receives quantized ML configuration information from the UE as described at 525 of FIG. 5 and recovers the ML configuration information in accordance with the quantization formats specified by the quantization configuration. The quantized ML configuration information can include a quantized ML configuration that indicates an ML configuration for forming a DNN and/or a quantized ML configuration update that indicates an ML configuration update to the DNN.

FIG. 7 illustrates an example method 700 for communicating quantized ML configuration information over a wireless network. In aspects, operations of the method 700 are performed by a user equipment, such as the UE 110.

At 705, a UE receives, over a wireless network, a quantization configuration for quantizing ML configuration information for a DNN, where the quantization configuration specifies one or more quantization formats associated with quantizing the ML configuration information. To illustrate, and as described at 520 of FIG. 5, the UE (e.g., the UE 110) receives the quantization configuration from a base station (e.g., the base station 120), such as in an RRC message. This can include the UE receiving the quantization configuration in a unicast message, a broadcast message, and/or a multicast message. The specified quantization formats may be used by the UE to quantize ML configuration information and/or recover ML configuration information from the quantized ML configuration information.

At 710, the UE transfers, over the wireless network and with a base station, quantized ML configuration information generated in accordance with the quantization configuration. For example, and as described at 525 of FIG. 5, the UE (e.g., the UE 110) receives quantization ML configuration information from the base station (e.g., the base station 120) and recovers the ML configuration information in accordance with the one or more quantization formats specified by the quantization configuration. Alternatively or additionally, the UE (e.g., the UE 110) transmits quantized ML configuration information to the base station (e.g., the base station 120) by quantizing the ML configuration information in accordance with the one or more quantization formats specified by the quantization configuration and as described at 525 of FIG. 5. The quantized ML configuration information can include a quantized ML configuration that indicates an ML configuration for forming a DNN and/or a quantized ML configuration update that indicates an ML configuration update to the DNN.

Although aspects of quantized ML configuration information have been described in language specific to features and/or methods, the subject of the appended claims is not necessarily limited to the specific features or methods described. Rather, the specific features and methods are disclosed as example implementations of quantized ML configuration information, and other equivalent features and methods are intended to be within the scope of the appended claims. Further, various different aspects are described, and it is to be appreciated that each described aspect can be implemented independently or in connection with one or more other described aspects.

In the following, some examples are described:

Example 1: A method performed by a base station for communicating quantized machine-learning, ML, configuration information over a wireless network, the method comprising:
selecting a quantization configuration for quantizing ML configuration information for a deep neural network, DNN, the quantization configuration specifying one or more quantization formats associated with quantizing the ML configuration information;
transmitting an indication of the quantization configuration to a user equipment, UE; and
transferring, over the wireless network and with the UE, quantized ML configuration information generated in accordance with the quantization configuration.

Example 2: The method as recited in claim 1, wherein selecting the quantization configuration further comprises:
receiving, over the wireless network and from the UE, user equipment-machine learning-quantization, UE-ML-quantization, capabilities; and
selecting the quantization configuration, based on the UE-ML-quantization capabilities.

Example 3: The method as recited in claim 1 or claim 2, wherein selecting the quantization configuration further comprises:
selecting the one or more quantization formats for at least one layer of the DNN, the one or more quantization formats including at least one of:
a vector quantization format;
a scalar quantization format; or
a sparsity quantization format.

Example 4: The method as recited in claim 3, wherein selecting the quantization configuration further comprises:
selecting the quantization configuration based on a number of layers included in the DNN; or selecting the quantization configuration based on a number of nodes included in a layer of the DNN.

Example 5: The method as recited in claim 4, wherein selecting the quantization configuration based on the number of layers further comprises:
selecting the scalar quantization format when the number of layers is less than a threshold value; or
selecting the vector quantization format when the number of layers is equal to or greater than the threshold value.

Example 6: The method as recited in any one of claims 1 to 5, wherein selecting the quantization configuration further comprises:
selecting a first quantization configuration for a first layer of the DNN; and
selecting a second quantization configuration for a second layer of the DNN, wherein the first quantization configuration is different from the second quantization configuration.

Example 7: The method as recited in any one of claims 1 to 6, wherein transmitting the indication of the quantization configuration further comprises:
transmitting the indication of the quantization configuration in a radio resource control, RRC, message.

Example 8: The method as recited in any one of claims 1 to 7, further comprising: selecting one or more quantization codebooks; and
communicating, to the UE, the selected one or more quantization codebooks.

Example 9: The method as recited in claim 8, wherein selecting the one or more quantization codebooks further comprises:
selecting the one or more quantization codebooks based on at least one of:
a codebook size supported by the UE; or
a codebook-adaptability mode supported by the UE.

Example 10: The method as recited in claim 8 or claim 9, wherein selecting the quantization configuration further comprises:
selecting a first quantization codebook, of the one or more quantization codebooks, for a first layer of the DNN; and
selecting a second quantization codebook, of the one or more quantization codebooks, for a second layer of the DNN.

Example 11: The method as recited in any one of claims 8 to 10, further comprising:
selecting one or more codebook-scaling factors for the one or more quantization codebooks; and
communicating, to the UE, the one or more codebook-scaling factors.

Example 12: The method as recited in any one of claims 8 to 11, wherein selecting the one or more quantization codebooks further comprises:
selecting, as at least one of the one or more quantization codebooks, a complex codebook that stores one or more complex numerical formats.

Example 13: The method as recited in any one of claims 1 to 12, further comprising:
selecting a distance metric that specifies an acceptable divergence amount for the ML configuration information; and
indicating the distance metric to the UE.

Example 14: The method as recited in any one of claims 1 to 13, wherein transferring the quantized ML configuration information further comprises:
transmitting the quantized ML configuration information to the UE over the wireless network; or
receiving the quantized ML configuration information from the UE over the wireless network.

Example 15: The method as recited in claim 14, wherein:
(i) transferring the quantized ML configuration information comprises transmitting the quantized ML configuration information to the UE, and the method further comprises: quantizing the ML configuration information in accordance with the one or more quantization formats specified by the quantization configuration; or
(ii) transferring the ML configuration information comprises receiving the quantized ML configuration information from the UE, and the method further comprises:
recovering the ML configuration information from the quantized ML configuration information in accordance with the one or more quantization formats specified by the quantization configuration.

Example 16: The method as recited in any one of claims 1 to 15, wherein the ML configuration information and the quantized ML configuration information comprises:
an ML configuration and a quantized ML configuration; or
an ML configuration update and a quantized ML configuration update.

Example 17: A method performed by a user equipment, UE, for communicating a quantized machine-learning, ML, configuration information over a wireless network, the method comprising:
receiving, from a base station and over the wireless network, a quantization configuration for quantizing ML configuration information for a deep neural network, DNN, the quantization configuration specifying one or more quantization formats associated with quantizing the ML configuration information; and
transferring, over the wireless network and with the base station, quantized ML configuration information generated in accordance with the quantization configuration.

Example 18: The method as recited in claim 17, further comprising:
transmitting, over the wireless network and to the base station, user equipment-machine-learning-quantization, UE-ML-quantization, capabilities that are supported by the UE.

Example 19: The method as recited in claim 17 or claim 18, wherein receiving the quantization configuration further comprises:
receiving the one or more quantization formats for at least one layer of the DNN, the one or more quantization formats including at least one of:
a vector quantization format;
a scalar quantization format; or
a sparsity quantization format.

Example 20: The method as recited in any one of claims 17 to 19, wherein receiving the quantization configuration further comprises:
receiving a first quantization configuration for a first layer of the DNN; and
receiving a second quantization configuration for a second layer of the DNN, wherein the first quantization configuration is different from the second quantization configuration.

Example 21: The method as recited in any one of claims 17 to 20, wherein receiving the quantization configuration further comprises:
receiving the quantization configuration in a radio resource control, RRC, message.

Example 22: The method as recited in any one of claims 17 to 21, further comprising:
receiving, from the base station, an indication to utilize one or more quantization codebooks for communicating the quantized ML configuration information, and
wherein transferring the quantized ML configuration information further comprises: using the one or more quantization codebooks to transfer the quantized ML configuration information.

Example 23: The method as recited in claim 22, wherein using the one or more quantization codebooks to transfer the quantized ML configuration information further comprises:
quantizing the ML configuration information using the one or more quantization codebooks; or
recovering the ML configuration information from the quantized ML configuration information using the one or more quantization codebooks.

Example 24: The method as recited in claim 23, wherein using the one or more quantization codebooks further comprises:
using a first quantization codebook, of the one or more quantization codebooks, for communicating the quantized ML configuration information for a first layer of the DNN; and
using a second quantization codebook, of the one or more quantization codebooks, for communicating the quantized ML configuration information for a second layer of the DNN.

Example 25: The method as recited in any one of claims 22 to 24, further comprising:
receiving, from the base station, one or more codebook-scaling factors for the one or more quantization codebooks; and
transferring the quantized ML configuration information using the one or more codebook-scaling factors.

Example 26: The method as recited in any one of claims 24 to 25, wherein using the one or more quantization codebooks to transfer the quantized ML configuration information further comprises at least one of:
(i) selecting an entry in the one or more quantization codebooks; and communicating an index value that maps to the entry; or
(ii) using, as at least one of the one or more quantization codebooks, a complex codebook that stores one or more complex numerical formats.

Example 27: The method as recited in any one of claims 17 to 26, further comprising:
receiving, from the base station, a distance metric that specifies an acceptable divergence amount for the quantized ML configuration information; and
quantizing the ML configuration information using the distance metric.

Example 28: The method as recited in any one of claims 17 to 27, wherein transferring the ML configuration information further comprises:
transmitting the quantized ML configuration information to the base station over the wireless network; or
receiving the quantized ML configuration information from the base station over the wireless network.

Example 29: The method as recited in claim 28, wherein:
(i) transferring the quantized ML configuration information comprises transmitting the quantized ML configuration information to the base station, and the method further comprises: quantizing the ML configuration information in accordance with the one or more quantization formats specified by the quantization configuration; or
(ii) transferring the ML configuration information comprises receiving the quantized ML configuration information from the base station, and the method further comprises: recovering the ML configuration information from the quantized ML configuration information in accordance with the one or more quantization formats specified by the quantization configuration.

Example 30: The method as recited in any one of claims 17 to 29, wherein the ML configuration information and the quantized ML configuration information comprises:
an ML configuration and a quantized ML configuration; or
an ML configuration update and a quantized ML configuration update.

Example 31: An apparatus comprising:
a wireless transceiver;
a processor; and
computer-readable storage media comprising instructions that, responsive to execution by the processor, direct the apparatus to perform a method as recited in any one of claims 1 to 30.

Example 32: Computer-readable storage media comprising instructions that, responsive to execution by a processor, direct an apparatus to perform a method as recited in any one of claims 1 to 30.

What is claimed is:

1. A method of wireless communication at a base station, the method comprising:
selecting a quantization configuration for quantizing machine-learning, ML, configuration information for a deep neural network, DNN, the quantization configuration specifying one or more quantization formats associated with quantizing the ML configuration information for at least one layer of the DNN, the selecting the quantization configuration comprising selecting the one or more quantization formats for the at least one layer of the DNN, the one or more quantization formats including at least one of a vector quantization format, a scalar quantization format, or a sparsity quantization format;
transmitting an indication of the quantization configuration to a user equipment, UE; and
transferring, over a wireless network and to the UE, quantized ML configuration information generated in accordance with the quantization configuration.

2. The method as recited in claim 1, wherein selecting the quantization configuration based on a number of layers further comprises:
selecting the scalar quantization format when the number of layers is less than a threshold value; or
selecting the vector quantization format when the number of layers is equal to or greater than the threshold value.

3. The method as recited in claim 1, wherein selecting the quantization configuration further comprises:
selecting a first quantization configuration for a first layer of the DNN; and
selecting a second quantization configuration for a second layer of the DNN, wherein the first quantization configuration is different from the second quantization configuration.

4. The method as recited in claim 1, further comprising:
selecting one or more quantization codebooks; and
communicating, to the UE, the one or more quantization codebooks responsive to selecting the one or more quantization codebooks.

5. The method as recited in claim 4, wherein selecting the one or more quantization codebooks further comprises:
selecting the one or more quantization codebooks based on at least one of:
a codebook size supported by the UE; or
a codebook-adaptability mode supported by the UE.

6. The method as recited in claim 4, further comprising:
selecting one or more codebook-scaling factors for the one or more quantization codebooks; and
communicating, to the UE, the one or more codebook-scaling factors.

7. The method as recited in claim 1, further comprising:
selecting a distance metric that specifies an acceptable divergence amount for the ML configuration information; and
indicating the distance metric to the UE.

8. The method as recited in claim 7, wherein:
transferring the quantized ML configuration information comprises transmitting the quantized ML configuration information to the UE, and the method further comprises:
quantizing the ML configuration information in accordance with the one or more quantization formats specified by the quantization configuration; or
transferring the ML configuration information comprises receiving the quantized ML configuration information from the UE, and the method further comprises:
recovering the ML configuration information from the quantized ML configuration information in accordance with the one or more quantization formats specified by the quantization configuration.

9. A method of wireless communication at a user equipment, UE, the method comprising:
receiving, from a base station and over a wireless network, a quantization configuration for quantizing machine learning, ML, configuration information for a deep neural network, DNN, the quantization configuration specifying one or more quantization formats associated with quantizing the ML configuration information, the receiving the quantization configuration further comprising:
receiving the one or more quantization formats for at least one layer of the DNN, the one or more quantization formats including at least one of:
a vector quantization format;
a scalar quantization format; or
a sparsity quantization format; and
transferring, over the wireless network and to the base station, quantized ML configuration information generated in accordance with the quantization configuration.

10. The method as recited in claim 9, wherein receiving the quantization configuration further comprises:
receiving a first quantization configuration for a first layer of the DNN; and
receiving a second quantization configuration for a second layer of the DNN, wherein the first quantization configuration is different from the second quantization configuration.

11. The method as recited in claim 9, further comprising:
receiving, from the base station, an indication to utilize one or more quantization codebooks for communicating the quantized ML configuration information, and
wherein transferring the quantized ML configuration information further comprises:
using the one or more quantization codebooks to transfer the quantized ML configuration information.

12. The method as recited in claim 11, further comprising:
receiving, from the base station, one or more codebook-scaling factors for the one or more quantization codebooks; and
transferring the quantized ML configuration information using the one or more codebook-scaling factors.

13. The method as recited in claim 9, further comprising:
receiving, from the base station, a distance metric that specifies an acceptable divergence amount for the quantized ML configuration information; and
quantizing the ML configuration information using the distance metric.

14. The method as recited in claim 13, wherein:
transferring the quantized ML configuration information comprises transmitting the quantized ML configuration information to the base station, and the method further comprises:
quantizing the ML configuration information in accordance with the one or more quantization formats specified by the quantization configuration; or
transferring the ML configuration information comprises receiving the quantized ML configuration information from the base station, and the method further comprises:
recovering the ML configuration information from the quantized ML configuration information in accordance with the one or more quantization formats specified by the quantization configuration.

15. A network entity apparatus comprising:
a processor;
a wireless communication hardware;
and
computer-readable storage media storing instructions that, when executed by the processor, cause the processor and the wireless communication hardware to:
select a quantization configuration for quantizing machine-learning, ML, configuration information for a deep neural network, DNN, the quantization configuration specifying one or more quantization formats associated with quantizing the ML configuration information for at least one layer of the DNN, to select the quantization configuration comprising to select the one or more quantization formats for the at least one layer of the DNN, the one or more quantization formats including at least one of a vector quantization format, a scalar quantization format, or a sparsity quantization format;
transmit an indication of the quantization configuration to a user equipment, UE; and
transfer, over a wireless network and to the UE, quantized ML configuration information generated in accordance with the quantization configuration.

16. The method as recited in claim 1, wherein selecting the quantization configuration further comprises:
selecting the quantization configuration based on a number of layers included in the DNN; or
selecting the quantization configuration based on a number of nodes included in a layer of the DNN.

17. The method as recited in claim 4, wherein selecting the quantization configuration further comprises:
selecting a first quantization codebook, of the one or more quantization codebooks, for a first layer of the DNN; and
selecting a second quantization codebook, of the one or more quantization codebooks, for a second layer of the DNN.

18. The method as recited in claim 4, wherein selecting the one or more quantization codebooks further comprises:
selecting, as at least one of the one or more quantization codebooks, a complex codebook that stores one or more complex numerical formats.

19. The method as recited in claim 1, wherein transferring the quantized ML configuration information further comprises:
transmitting the quantized ML configuration information to the UE over the wireless network; or
receiving the quantized ML configuration information from the UE over the wireless network.

20. The method as recited in claim 1, wherein the ML configuration information and the quantized ML configuration information comprises:
an ML configuration and a quantized ML configuration; or
an ML configuration update and a quantized ML configuration update.
